(19) United States
(12) Patent Application Publication
(10) Pub. No.: US 2015/0280167 A1
(43) Pub. Date: Oct. 1, 2015

(54) PACKAGING COVER PLATE FOR ORGANIC LIGHT-EMITTING DEVICE, ORGANIC LIGHT-EMITTING DEVICE AND DISPLAY DEVICE HAVING THE SAME

(71) Applicant: BOE TECHNOLOGY GROUP CO., LTD., Beijing (CN)

(72) Inventor: Jiahao Zhang, Beijing (CN)

(21) Appl. No.: 14/236,303

(22) PCT Filed: Aug. 12, 2013
(86) PCT No.: PCT/CN2013/081313

§ 371 Date: Jan. 30, 2014

(30) Foreign Application Priority Data
Jun. 19, 2013 (CN) 201310244941.5

(51) Int. Cl. H01L 51/52

(52) U.S. Cl. CPC H01L 51/524

(57) ABSTRACT

Disclosed are a packaging cover plate for an organic light-emitting device (OLED), an OLED, and a display device. The packaging cover plate may comprise a packaging surface bonded with a substrate using a packaging adhesive, wherein a groove structure for accommodating the packaging adhesive is formed on a periphery of the package surface of the packaging cover plate.

### BACKGROUND OF THE INVENTION

1. Field of the Invention

The present disclosure relates to the field of organic light-emitting display technologies, and in particular, relates to a packaging cover plate for an organic light-emitting device, an organic light-emitting device, and a display device having the organic light-emitting device.

2. Description of the Prior Art

In recent years, an organic light-emitting device (OLED), which emits tender, more natural and high-brightness light, features wide view-angle, quick response, high-efficiency and active light emitting, and is light and thin, becomes hotspot of research in such fields as full-color display, backlight, and illumination.

The OLED is sensitive to water and oxygen contents, and water and oxygen may cause the OLED to fail. Typically, water and oxygen react with pin holes in the metal cathode (generally Al) of the OLED, such that the metal cathode is subject to stripping and the pin holes are developed into black dots. The back dots are enlarged as prevailing over the entire light-emitting device due to stripping of the metal cathode as reacting with water and oxygen. Therefore, to eliminate impacts caused by water and oxygen onto the OLED, the OLED needs to be packaged.

A commonly-used solution to address such problem is to arrange a light-emitting device into a sealed space by bonding a packaging cover plate (made of a glass material or other materials) with a substrate in an atmosphere of inert gas. As illustrated in FIG. 1, a packaging cover plate 10 has a traditional OLED is a smooth surface. The smooth surface is coated with a packaging adhesive 30 and then bonded with a substrate 20, thereby implementing packaging of the OLED. In this case, the gap between the packaging cover plate and the substrate is large; and packaging of the OLED depends on the packaging adhesive 30. However, the packaging adhesive 30 is subject to the curing defect, and defects such as porosity and poor bonding force with the substrate, and thus is poor in the vapor barrier performance. Therefore, the gap between the packaging cover plate and the substrate should be reduced as much as possible to reduce the lateral area which water and oxygen may permeate, thereby effectively improving the packaging effect. In the conventional art, protruding packaging rings fabricated by a glass adhesive may be arranged on the packaging surface of the packaging cover plate to mitigate permeation of the vapor. This structure is simple in fabrication, but is disadvantageous in that the glass adhesive is costly. Therefore, the cost of the OLED using such structure is high. In addition, the height of the protruding packaging ring can hardly be controlled. Especially when the height is smaller than 10 μm, during lamination, gap uniformity of the glass is poor.

### SUMMARY OF THE INVENTION

The present disclosure is directed to providing a packaging cover plate for an OLED, and an OLED having the packaging cover plate, and a display device having the OLED, which are capable of improving lateral barrier properties of the OLED packaging, effectively preventing water and oxygen from permeating the OLED, and prolonging the service life of the OLED.

The present disclosure provides technical solutions as follows:

A packaging cover plate for an OLED is provided, the packaging cover plate comprising a packaging surface bonded with a substrate using a packaging adhesive, wherein a groove structure for accommodating the packaging adhesive is formed on a periphery of the packaging surface of the packaging cover plate.

Preferably, the groove structure comprises at least one first annular groove formed by contiguously encircling the periphery of the packaging surface.

Preferably, the groove structure comprises at least one second curved groove formed by contiguously encircling the periphery of the packaging surface.

Preferably, the groove structure further comprises at least one third annular or curved groove formed by non-contiguously encircling the periphery of the packaging surface.

Preferably, a receiving chamber for accommodating an anode layer, an organic light-emitting layer, and a cathode layer of the OLED is formed at a middle portion of the packaging surface of the packaging cover plate; and the groove structure is formed on a periphery of the receiving chamber.

Preferably, the packaging cover plate of the OLED is a glass packaging cover plate; and the groove structure is formed on the packaging surface of the glass packaging cover plate by means of etching.

Preferably, the groove structure has a depth of not larger than 100 μm.

An OLED is provided, comprising a substrate, an anode layer, an organic light-emitting layer, a cathode layer, and a packaging cover plate; wherein the packaging cover plate is the above-described packaging cover plate.

A display device is provided, comprising the above-described OLED.

The present disclosure achieves the following beneficial effects:

According to the above solutions, a groove structure is arranged on the packaging surface of the packaging cover plate. During packaging of an OLED by employing the packaging cover plate, a packaging adhesive for bonding the packaging cover plate and a substrate is filled in the groove structure on the packaging cover plate. In this way, the gap between the packaging cover plate and the substrate is greatly reduced, which results in that permeating paths of the moisture or vapor are reduced, improving the packaging effect of the OLED, and prolonging the service life of the OLED.

According to a further solution of the present disclosure, the packaging cover plate according to the present disclosure employs a glass packaging substrate. In addition, the groove structure is fabricated by means of etching. The fabrication is convenient; and the depth of the groove may be easily controlled. This achieves a uniform gap between the packaging cover plate and the substrate, which reduces the costs.

### BRIEF DESCRIPTION OF THE DRAWINGS

FIG. 1 is a schematic view of a traditional OLED;

FIG. 2 is a schematic cross-sectional view of a packaging cover plate for an OLED according to a first embodiment of the present disclosure;

FIG. 3 is a schematic cross-sectional view of an OLED according to the present disclosure;

FIG. 4 is a schematic front view of a packaging cover plate for an OLED according to the first embodiment of the present disclosure;

FIG. 5 is a schematic front view of a packaging cover plate for an OLED according to a second embodiment of the present disclosure; and

FIG. 6 is a schematic front view of a packaging cover plate for an OLED according to a fourth embodiment of the present disclosure.

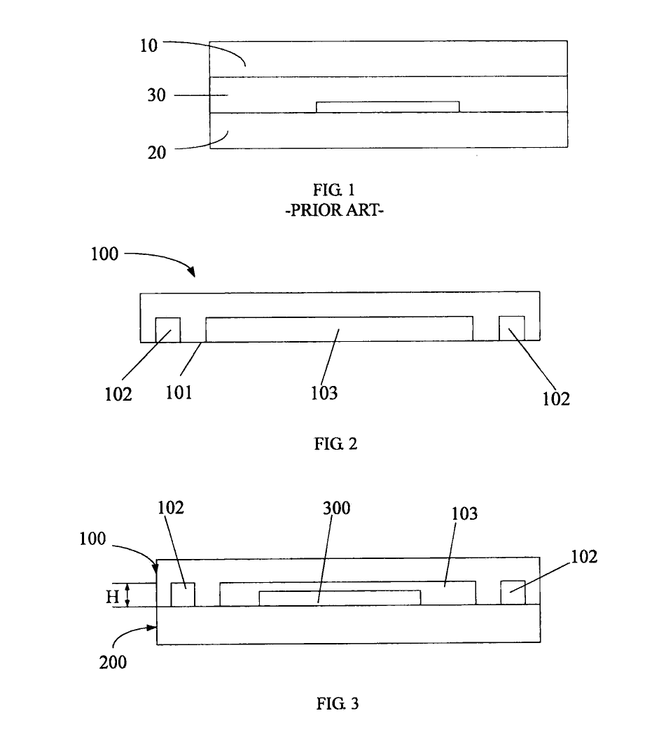

### DETAILED DESCRIPTION OF THE PREFERRED EMBODIMENTS

Principles and features of the present disclosure are described with reference to the attached drawings, and examples hereinafter are merely for illustrating the present disclosure, and not intended to limit the scope of the present disclosure.

FIG. 2 is a schematic cross-sectional view of a packaging cover plate for an OLED according to the present disclosure. As illustrated in FIG. 2, a packaging cover plate 100 for OLED is provided, the packaging cover plate 100 comprising a packaging surface 101 bonded with a substrate using a packaging adhesive. A groove structure 102 for accommodating the packaging adhesive is formed on a periphery of the packaging surface 101.

A receiver chamber 103 for accommodating an anode layer, an organic light-emitting layer, and a cathode layer of the OLED is formed at a middle portion of the packaging surface of the packaging cover plate 100. And the groove structure 102 is formed on a periphery of the receiving chamber 103.

FIG. 3 is a schematic cross-sectional view of an OLED having the packaging cover plate 100 according to the present disclosure. As illustrated in FIG. 3, during packaging of the OLED by using the packaging cover plate 100 according to the present disclosure, a light-emitting device body 300 of the OLED, which is formed by an anode layer, an organic light-emitting layer, and a cathode layer, is arranged in the receiving chamber 103 of the packaging cover plate 100, while the packaging adhesive is filled in the receiving chamber 103 to fix the light-emitting device body 300. The groove structure arranged on the periphery of the packaging surface 101 of the packaging cover plate 100 is also filled with the packaging adhesive such that the packaging cover plate 100 is bonded with a substrate 200, thereby achieving device packaging. Since the packaging adhesive is filled in the groove structure 102 on the packaging cover plate 100, a much smaller gap is formed between the packaging cover plate 100 and the substrate 200 of the OLED (in the case of a traditional OLED, the gap between the packaging cover plate 100 and the substrate 200 may be from 10 to 30 mm; whereas in the case of the OLED having the packaging cover plate 100 according to the present disclosure, the gap between the packaging cover plate 100 and the substrate 200 may be reduced to be smaller than 5 μm). Therefore, the lateral area of the packaged OLED, which water and oxygen in the ambient environment may permeate, is reduced, thereby effectively reducing the permeating paths of water and oxygen, and improving the lateral barrier properties of the OLED packaging.

It should be noted that, in practice, the receiving chamber 103 for accommodating the anode layer, the organic light-emitting layer, and the cathode layer of the OLED may not be arranged on the packaging cover plate 100. Instead, the packaging cover plate 100 cooperates with the substrate 200 of the OLED, where the receiving chamber 103 is arranged.

In addition, the groove structure 102 on the packaging cover plate 100 of the OLED according to the present disclosure is implemented as follows.

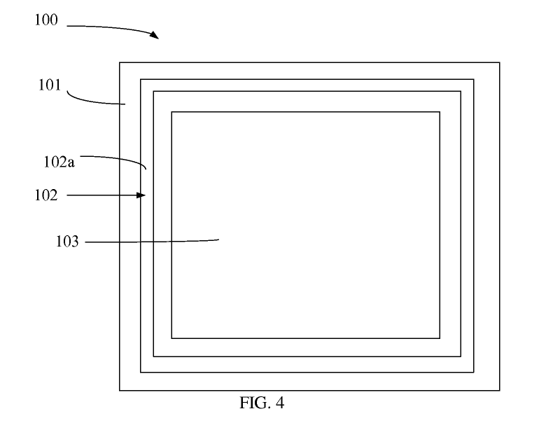

FIG. 4 is a schematic front view of the packaging cover plate 100 according to a first embodiment of the present disclosure. As illustrated in FIG. 4, in the first embodiment of the present disclosure, the groove structure 102 on the packaging cover plate 100 comprises only one first annular groove 102a formed by contiguously encircling the periphery of the packaging surface 101 of the packaging cover plate 100. With the above solution, since the first annular groove 102a contiguously encircles the periphery of the packaging surface 101 of the packaging cover plate 100, a uniform gap is achieved between the periphery of the packaging cover plate 100 and the substrate 200, thereby improving the lateral barrier properties of the periphery of the OLED.

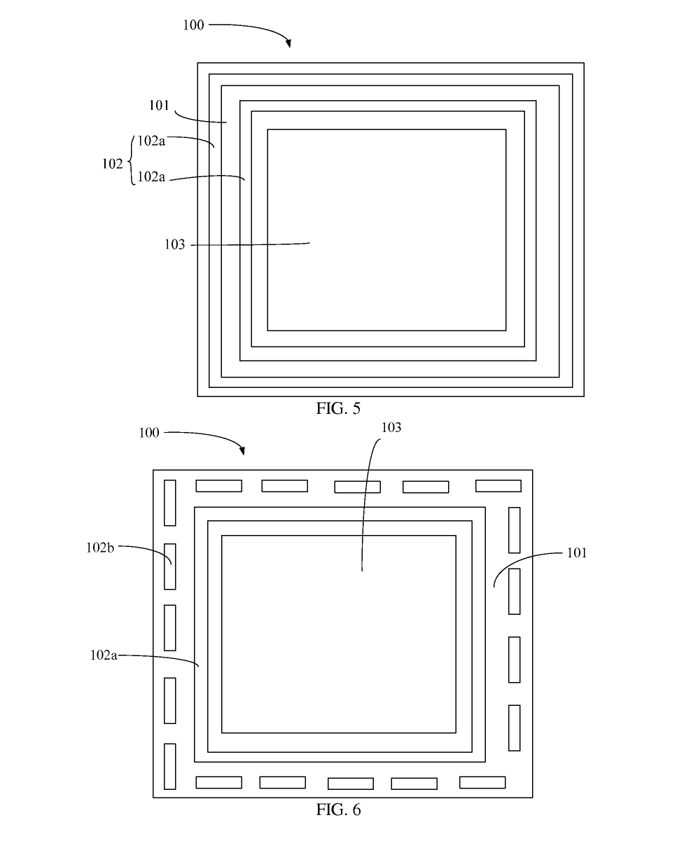

FIG. 5 is a schematic front view of the packaging cover plate 100 according to a second embodiment of the present disclosure. As illustrated in FIG. 5, in the second embodiment of the present disclosure, the groove structure 102 on the packaging cover plate 100 comprises a plurality of first annular grooves 102a formed by contiguously encircling the periphery of the packaging surface 101 of the packaging cover plate 100. With the above solution, vapor or moisture is prevented from permeating the OLED.

In a third embodiment of the present disclosure, the groove structure 102 on the packaging cover plate 100 comprises at least one second curved groove formed by contiguously encircling the periphery of the packaging surface 101 of the packaging cover plate 100. With the above solution, the second curved groove at least encircles the packaging surface 101 by one round to ensure that the periphery gap between the packaging cover plate 100 and the periphery of the substrate 200 is reduced. It should be understood that, in practice, a plurality of second curved grooves may be employed, and the number of second grooves is not limited herein.

FIG. 6 is a schematic front view of the packaging cover plate 100 according to a fourth embodiment of the present disclosure. As illustrated in FIG. 6, in the fourth embodiment of the present disclosure, the groove structure 102 comprises at least one first annular or curved groove 102a (FIG. 6 only illustrates a first groove 102a in a annular shape) formed by encircling the periphery of the packaging surface. And the groove structure 102 may further comprise a third annular groove 102b formed by encircling the periphery of the packaging surface 101. It should be understood that, in practice, a plurality of third grooves may be employed; and the number of third grooves is not limited herein. It should be additionally noted that the third groove may curve around the periphery of the packaging surface.

It should be additionally noted that, described above are merely several preferred embodiments illustrating the packaging cover plate 100. In practice, the groove structure 102 may be a combination of structures illustrated in these embodiments, or may not be limited to the structures illustrated therein.

In addition, in the packaging cover plate 100 of the OLED according to the present disclosure, preferably, the packaging cover plate 100 may be a glass packaging cover plate 100. And the groove structure 102 on the packaging cover plate 100 may be fabricated by means of exposure, developing and etching. The above fabrication process is simple and cost-effective; and the depth and width of the groove structure 102 can be easily controlled, thereby achieving a uniform gap between the glass packaging cover plate 100 and the substrate 200.

In addition, in the packaging cover plate 100 of the OLED according to the present disclosure, preferably, the depth H of the groove structure 102 is not larger than 100 μm. In this way, impacts caused by the groove structure 102 onto the strength of the packaging cover plate 100 may be mitigated. Further, in practice, the width of the groove structure may be adjusted according to the dimension of the packaging cover plate 100 under the premise of not affecting the strength of the packaging cover plate 100.

In addition, as illustrated in FIG. 3, an embodiment of the present disclosure further provides an OLED, comprising a substrate 200, an anode layer, an organic light-emitting layer, and a cathode layer, and the packaging cover plate according to the present disclosure.

Further, an embodiment of the present disclosure further provides a display device having the above-described OLED.

Described above are preferred embodiments of the present disclosure. It should be noted that persons of ordinary skill in the art may derive other improvements or modifications without departing from the principles of the present disclosure. Such improvements and modifications shall be deemed as falling within the protection scope of the present disclosure.

1. A packaging cover plate for an organic light-emitting device, the packaging cover plate comprising a packaging surface bonded with a substrate using a packaging adhesive, wherein a groove structure for accommodating the packaging adhesive is formed on a periphery of the packaging surface of the packaging cover plate.

2. The packaging cover plate for an organic light-emitting device according to claim 1, wherein
the groove structure comprises at least one first annular groove formed by contiguously encircling the periphery of the packaging surface.

3. The packaging cover plate for an organic light-emitting device according to claim 1, wherein
the groove structure comprises at least one second curved groove formed by contiguously encircling the periphery of the packaging surface.

4. The packaging cover plate for an organic light-emitting device according to claim 2, wherein
the groove structure further comprises at least one third annular or curved groove formed by non-contiguously encircling the periphery of the packaging surface.

5. The packaging cover plate for an organic light-emitting device according to claim 1, wherein
a receiving chamber for accommodating an anode layer, an organic light-emitting layer, and a cathode layer of the organic light-emitting device is formed at a middle portion of the packaging surface of the packaging cover plate; and
the groove structure is formed on a periphery of the receiving chamber.

6. The packaging cover plate for an organic light-emitting device according to claim 1, wherein
the packaging cover plate of the organic light-emitting device is a glass packaging cover plate; and
the groove structure is formed on the packaging surface of the glass packaging cover plate by means of etching.

7. The packaging cover plate for an organic light-emitting device according to claim 1, wherein the groove structure has a depth of not larger than 100 μm.

8. An organic light-emitting device, comprising a substrate, an anode layer, an organic light-emitting layer, a cathode layer, and a packaging cover plate; wherein the packaging cover plate comprises a packaging surface bonded with a substrate using a packaging adhesive, wherein a groove structure for accommodating the packaging adhesive is formed on a periphery of the packaging surface of the packaging cover plate.

9. A display device, comprising an organic light-emitting device, wherein the organic light-emitting device comprises: a substrate, an anode layer, an organic light-emitting layer, a cathode layer, and a packaging cover plate; wherein the packaging cover plate comprises a packaging surface bonded with a substrate using a packaging adhesive, and wherein a groove structure for accommodating the packaging adhesive is formed on a periphery of the packaging surface of the packaging cover plate.

10. The organic light-emitting device according to claim 8, wherein
the groove structure comprises at least one first annular groove formed by contiguously encircling the periphery of the packaging surface.

11. The organic light-emitting device according to claim 8, wherein
the groove structure comprises at least one second curved groove formed by contiguously encircling the periphery of the packaging surface.

12. The organic light-emitting device according to claim 10, wherein
the groove structure further comprises at least one third annular or curved groove formed by non-contiguously encircling the periphery of the packaging surface.

13. The organic light-emitting device according to claim 8, wherein
a receiving chamber for accommodating an anode layer, an organic light-emitting layer, and a cathode layer of the organic light-emitting device is formed at a middle portion of the packaging surface of the packaging cover plate; and
the groove structure is formed on a periphery of the receiving chamber.

14. The organic light-emitting device according to claim 8, wherein
the packaging cover plate of the organic light-emitting device is a glass packaging cover plate; and
the groove structure is formed on the packaging surface of the glass packaging cover plate by means of etching.

15. The organic light-emitting device according to claim 8, wherein the groove structure has a depth of not larger than 100 μm.

16. The display device according to claim 9, wherein
the groove structure comprises at least one first annular groove formed by contiguously encircling the periphery of the packaging surface.

17. The display device according to claim 9, wherein
the groove structure comprises at least one second curved groove formed by contiguously encircling the periphery of the packaging surface.

18. The display device according to claim 16, wherein
the groove structure further comprises at least one third annular or curved groove formed by non-contiguously encircling the periphery of the packaging surface.

19. The display device according to claim 9, wherein a receiving chamber for accommodating an anode layer, an organic light-emitting layer, and a cathode layer of the organic light-emitting device is formed at a middle portion of the packaging surface of the packaging cover plate; and
the groove structure is formed on a periphery of the receiving chamber.

20. The display device according to claim 9, wherein
the packaging cover plate of the organic light-emitting device is a glass packaging cover plate; and
the groove structure is formed on the packaging surface of the glass packaging cover plate by means of etching.
